(19) United States
(12) Patent Application Publication
(10) Pub. No.: US 2008/0079415 A1
(43) Pub. Date: Apr. 3, 2008

(54) DEVICE AND METHOD FOR DETERMINING THE INTENSITY OF CURRENT

(76) Inventors: Dan Mirescu, Caen (FR); Guillaume Prevot, Cleville (FR)

Correspondence Address: CARLSON, GASKEY & OLDS, P.C., 400 WEST MAPLE ROAD, SUITE 350, BIRMINGHAM, MI, 48009, US

(21) Appl. No.: 11/863,613

(22) Filed: Sep. 28, 2007

(30) Foreign Application Priority Data
Sep. 28, 2006 (FR) 0608517

(51) Int. Cl. G01R 19/02

(52) U.S. Cl. 324/76.11

(57) ABSTRACT

A device allows current flowing in each branch of a multi-channel circuit to be evaluated. The device includes secondary branches in parallel with each other and which each receive a resistive component. The device also includes a main branch with a resistive component, the main branch being connected in series with the secondary branches, and a control unit that analyzes the voltages measured across the terminals of each of the resistive components and deduces the value of the current flowing through each of the resistive components. A method for determining the intensity of electrical currents is performed using the device. The currents can be measured in several branches in a less expensive manner. The temperature of the device can also be determined.

### REFERENCE TO RELATED APPLICATIONS

This application claims priority to French Patent Application No. FR 06 08 517 filed on Sep. 28, 2006.

### BACKGROUND OF THE INVENTION

The present invention relates to a device and method for determining or evaluating the intensity of current.

There are systems for which there is a need to know a value of an electrical current. For example, anti-pinch systems can detect the pinching of an object by an automobile vehicle door window. These systems notably detect the pinching by detecting a variation in power supply current to a power window motor. The intensity of the current must therefore be known. For this purpose, a shunt placed in an electrical power supply circuit of the power window motor may be used. The shunt is an accurately calibrated resistor, which allows the value of the power supply current to the power window motor to be deduced by measuring voltage across terminals of the shunt. In one example, the shunt is constructed in such a manner that its resistance is accurately known and does not vary as a function of temperature. The shunt is therefore an expensive component.

Now, in a vehicle for example, several current intensities may need to be determined. The vehicle may include several anti-pinch systems, rear-view mirror adjustment systems, etc. The current intensity relating to the operation of each of these systems is potentially of interest. However, the determination of the current intensity in each of these systems is expensive if the current intensity is determined with a shunt.

There is therefore a need for a less expensive device that allows a plurality of current intensities to be determined.

### SUMMARY OF THE INVENTION

The invention relates to a device that allows current flowing in each branch of a multi-channel circuit to be evaluated. The device includes secondary branches in parallel with each other and and which each receive a resistive component. The device also includes a main branch with a resistive component, the main branch being connected in series with the secondary branches, and a control unit that analyzes voltages measured across terminals of each of the resistive components and deduces the value of the current flowing through each of the resistive component.

According to one variant, the resistive component of the main branch has a predetermined resistance. According to one variant, the resistive component of the main branch is a shunt.

According to one variant, the resistive component of the secondary branches has a characteristic that varies as a function of temperature. According to one variant, the resistive component of the secondary branches has a resistance that varies as a function of temperature. According to one variant, the resistive component of the secondary branches is customized for each of the secondary branches as a function of nominal current that should flow through the resistive components, and all the resistive components vary according to the same law as a function of temperature. According to one variant, the control unit also determines the global temperature of the device.

The invention also relates to an architecture of a vehicle electrical system including the device as previously described. According to one variant, at least one of the secondary branches is chosen within a group including a power supply circuit of a power window motor, a power supply circuit of a rear-view mirror actuator motor, a power supply circuit of a lock actuating motor, a power supply circuit of a sun-roof actuating motor and a power supply circuit of a seat actuating motor.

The invention also relates to a method for determining an electrical current intensity in each of the branches of a device as previously described or in the architecture as previously described. The method includes the steps of measuring the voltage across the terminals of the resistive components of each of the main branch and the secondary branches and determining the intensity of the current in the branches as a function of the characteristic of the resistive component of the main branch. According to one variant, the temperature of the device is also determined.

### BRIEF DESCRIPTION OF THE DRAWINGS

Other features and advantages of the invention will become apparent upon reading the detailed description that follows of the embodiments of the invention, presented solely by way of example and with reference to the appended drawings, which show:

FIG. 1 illustrates an architecture according to one example of the invention.

### DETAILED DESCRIPTION OF THE PREFERRED EMBODIMENT

The invention relates to a device that allows current flowing in each branch of a multi-channel circuit to be evaluated. The device includes secondary branches in parallel with each other and which each receive a resistive component. The device also includes a main branch with a resistive component, where the main branch is connected in series with the secondary branches. The device also includes a control unit that analyzes voltages measured across terminals of each of the resistive components and deduces the value of current flowing through each of the resistive components. The device thus allows the current in several branches to be determined in a low-cost manner. Only the main branch includes a resistive component with known characteristics, which is hence more expensive, whereas the secondary branches include a resistive component with characteristics that vary with temperature, for example, and hence is inexpensive. Thus, rather than all the branches being equipped with an expensive component, only the main branch is thus equipped.

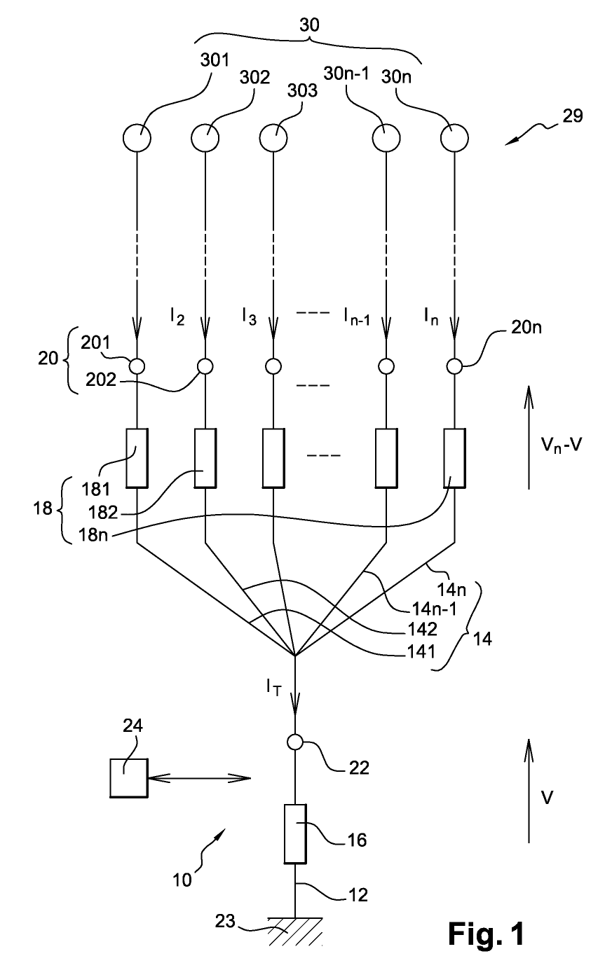

FIG. 1 shows an architecture 29 including a device 10. The device 10 includes a main circuit branch 12 and secondary circuit branches 14. The secondary branches 14 are in parallel with one another. Each of the secondary branches 14 is connected in series with the main branch 12. The main branch 12 includes a component of predetermined characteristics. The secondary branches 14 include a component of variable characteristics that vary according to the same variation law. The device 10 also includes an accessory for measuring voltage in the main and secondary branches 12 and 14, and a control unit 24 that determines the intensity of current in the main and secondary branches 12 and 14 as a function of the voltages in each of the main and secondary branches 12 and 14 and of the predetermined characteristic of the component of the main branch 12. The number n of the secondary branches 14 is greater than or equal to two. The n secondary branches 14 are referenced 141, 142, . . . , 14n. The main branch 12 and includes a resistive component 16, and the secondary branches 14 include a resistive component 18.

The resistive component 16 of the main branch 12 has a predetermined and known characteristic. In particular, the resistive component 16 is a resistive component with a predetermined resistance. The characteristic is predetermined in the sense that it does not vary as a function of external parameters. For example, the characteristic does not vary as a function of temperature. The component can be a shunt (calibrated resistor). The resistance of the shunt is predetermined and known in a precise manner. Preferably, a material will be chosen for the shunt such that the resistance of the shunt does not vary, notably, as a function of temperature.

The resistive component 181, 182, . . . , 18n of each of the secondary branches 14 has a variable characteristic. In particular, the resistive component 181, 182, . . . , 18n is a resistive component with a resistor whose resistance value can be variable. The characteristic is variable in the sense that it is able to vary as a function of external parameters. For example, the characteristic may vary as a function of temperature. With respect to the resistive component 16 of the main branch 12, the resistive component 181, 182, . . . , 18n of each of the secondary branches 14 has a less accurate characteristic. The resistive component 181, 182, . . . , 18n is, for example, a low-cost resistor whose behavior is likely to vary with temperature (of the component, or more generally of the device 10) during its use. The variation of the characteristic of the resistive component 181, 182, . . . , 18n as such is not desirable, but this variation makes the resistive component 181, 182, . . . , 182n inexpensive.

Nevertheless, the resistive component 181, 182, . . . , 18n has a characteristic varying in a known manner according to a variation law which is the same for the resistive components 181, 182, . . . , 18n. For example, the resistance that varies as a function of temperature can vary according to the following relationship: R=R0(1+αT+βT²+ . . . ), with R0 being the nominal resistance R1, R2, . . . , Rn of each resistive component 181, 182, . . . , 18n of the n secondary branches 14, T being the operating temperature, and α, β, . . . being the known temperature factors depending on the materials employed (for example, for copper, α=0.4%/° C.). For simplicity, the variable resistance of the components is written KR1, KR2, . . . , KRn, with K being the temperature coefficient corresponding to the variation term, or law, (1+αT+βT²+ . . . ) and R1, R2, . . . , Rn being the nominal resistance of each resistive component 181, 182, . . . 18n. It is assumed that the resistive components 18 are at the same temperature during the operation of the device 10. The nominal resistance of each resistive component 181, 182, . . . , 18n may or may not be the same, as indicated by the following. Preferably, the characteristics of the resistive components 181, 182, . . . , 18n vary according to the same variation law. In particular, the temperature coefficient K is the same for all the resistive components 181, 182, . . . , 18n and varies in the same fashion. The variation of the temperature coefficient allows the resistance of the resistive components 181, 182, . . . , 18n to be made to vary according to the same law. Thus, the ratio of the characteristics of the resistive components 181, 182, . . . , 18n over a nominal value of these characteristics varies in a similar fashion for all the branches 12 and 14.

The device 10 also includes a control unit 24 that analyzes the voltages measured across the terminals of each of the resistive components 16 and 18 and deduces the value of the current flowing through each of the resistive components. In other words, the control unit 24 determines the intensity of the current in the secondary branches 14 as a function of the voltages in each of the branches 12 and 14 and of the predetermined characteristic of the resistive component 16 of the main branch 12. This allows the variations in current intensity to be monitored in the secondary branches 14. The determination of the intensity of the currents is carried out in the manner hereinafter described.

According to FIG. 1, a current I1, I2, . . . , In flows through each of the secondary branches 14. Because the secondary branches 14 are each in series with the main branch 12, the current I flowing through the main branch 12 corresponds to the sum of the currents flowing through the secondary branches 14:1=I1+I2+ . . . +In. At the point referenced 201, 202, . . . 20n of each of the secondary branches 14, the potential is V1, V2, . . . , Vn. At the point referenced 22 of the main branch 12, the potential is V. These potentials are measured by a suitable accessory (for example, an accessory of the voltmeter type) of the device 10 at each of the points 201, 202, . . . , 20n, 22. The voltage across the terminals of each of the resistive components 18 corresponds to the potential difference V1-V, V2-V, . . . , Vn-V. The voltage across the terminals of the resistive component 16 corresponds to the difference between the potential V at the point 22 and ground potential 23 to which the main branch 12 is connected. Because ground potential 23 is zero, the voltage across the terminals of the resistive component 16 is V.

The voltage across the terminals of each resistive component 181, 182, . . . , 18n is obtained by the relationship U=RI, U being the voltage across the terminals of the component, R being the resistance of the component of the branch in question and I being the current flowing through the component. For each secondary branch 14, the relationship U=RI is written:

V1−V=KR1·I1;

V2−V=KR2−I2;

Vn−V=KRn·In.

For the main branch 12, V=R·I (with K=1 in this case, by way of example, because this component is stable with temperature) is obtained.

n equations are obtained corresponding to the n secondary branches 14 plus one equation for the main branch 12 (eq1, eq2, . . . , eqn plus eq(n+1)). By considering that the current I of the main branch 12 is equal to the sum of the currents of the secondary branches 14 (eq(n+1)), the following matrix is obtained:

$$\begin{matrix}\vert \begin{matrix}\underline{\vert \begin{matrix}{R}_{1} & 0 & … & 0 \\ 0 & {R}_{2} & … & 0 \\ … & … & … & … \\ 0 & 0 & … & {R}_{n}\end{matrix}} \\ \begin{matrix}K \cdot & {R}_{sh} & \cdot \vert & 1 & 1 & … & 1\end{matrix}\end{matrix} \vert \cdot & [ \begin{matrix}{I}_{1} \\ {I}_{2} \\ … \\ {I}_{n}\end{matrix} ] = [ \begin{matrix}{V}_{1} - V \\ {V}_{2} - V \\ … \\ {V}_{n} - V \\ V\end{matrix} ]\end{matrix} \qquad \begin{matrix}eq 1 \\ eq 2 \\ … \\ eq n \\ eq ( n + 1 )\end{matrix}$$

Because the main branch 12 includes a component of predetermined characteristic having a current equal to the sum of the currents of the secondary branches 14 flowing through it, a system of n+1 equations and as many unknowns (the currents I1 to In and K) are obtained. The solution of the system of equations is simple to carry out. The control unit 24 is programmed accordingly.

The solution of the system of equations not only allows the intensity values of the currents flowing through the secondary branches 14 to be accurately obtained, but K=(1+αT+βT²+ . . . ) is also obtained. The determination of K allows the temperature of the resistive components 18 to be determined without making use of a dedicated sensor, which is less expensive. The temperature is obtained with a degree of precision which depends on the number of temperature coefficients α, β, . . . used by the control unit 24.

FIG. 1 shows more generally an electrical architecture 29 including the device 10, such as previously described. The architecture 29 is, for example, implemented in an automobile vehicle. The vehicle can include one or more systems of the anti-pinch type that allows the detection of objects present in the travel of a window. The vehicle can also include adjustment systems 301, 302, . . . , 30n, such as for the adjustment of rear-view mirrors, sun-roof or seats or lock actuation systems, for which the measurement of the currents is useful for the control of the operation. The adjustment systems 301, 302, . . . , 30n include motors or actuating devices powered by a current. The secondary branches 14 of the device 10 are each connected to the respective power supply circuits of the adjustment systems 301, 302, . . . , 30n. Thus, the secondary branches 14 are powered by the power supply current of the respective system. Thus, the resistive component 181, 182, . . . , 18n of the secondary branches 14 is customized for each of the secondary branches 14 as a function of the nominal current that should flow through it, and all the resistive components 181, 182, . . . , 18n vary according to the same law as a function of temperature. The device 10 allows the power supply current of the systems to be determined and conclusions to be drawn from this. Thus, if the device 10 detects that one of the currents of the secondary branches 14 varies abnormally, the device 10 detects that the corresponding system is operating abnormally. For example, if an increase in current consumed by the drive motor of a power window system is detected by the device 10, this may be interpreted as the presence of an obstacle in the travel of the window driven by the power window system. The device 10 offers the advantage of being able to detect such operational anomalies for a lower cost, given that the secondary branches 14 have a low-cost component and that only the main branch 12 includes a component that is more expensive.

Preferably, the nominal resistances R1, R2, . . . , Rn are chosen according to the motors of the adjustment systems 301, 302, . . . , 30n in such a manner as to obtain voltages with close values across the terminals of the resistive components 181, 182, . . . , 18n. This allows voltages of close values to be obtained in the secondary branches 14 to facilitate the sizing of the device 10. Thus, the nominal resistances R1, R2, . . . , Rn will be inversely proportional to the power of the motors of the adjustment systems 301, 302, . . . , 30n. The higher the power supply current for the motors flowing through the secondary branches 14, the lower the value of the nominal resistance, and vice versa.

The invention also relates to a method for determining the electrical current intensity in each of the main and secondary branches 12 and 14 of a device 10 described previously or in the architecture 29 previously described. In this method, the voltage across the terminals of the respective resistive components 16 and 18 of the main branch 12 and secondary branches 14 is measured, and the intensity of the current in the main and secondary branches 12 and 14 is determined as a function of the characteristic of the component of the main branch 12. The intensity of the current in the main and secondary branches 12 and 14 is determined by solving the system of equations because of the predetermined characteristic of the component of the main branch 12. In other words, in this method for determining the intensity of electrical currents in the device 10 described previously, the voltage across the terminals of the respective resistance components 16 and 18 in the main and secondary branches 12 and 14 is measured, and the intensity of the current in the branches 12 and 14 is determined as a function of the voltages across the terminals of the components of each of the main and secondary branches 12 and 14 and as a function of the predetermined characteristic of the resistive component 16 of the main and secondary main branch 12. The method also allows the temperature of the resistive components 18 to furthermore be determined (assuming that the temperature is the same for all the resistive components 18). The advantages presented by the method are the same as those previously described.

The invention is not limited to the exemplary embodiments described. The variable characteristic of the resistive components 181, 182, . . . , 18n may vary according to other parameters than the temperature. Furthermore, the device 10 and the architecture 29 are shown in FIG. 1 by way of example, but are not limited to this example. Thus, one terminal of the resistive component 16 is not necessarily connected to ground potential 23, even though such a configuration is simple.

The foregoing description is only exemplary of the principles of the invention. Many modifications and variations are possible in light of the above teachings. It is, therefore, to be understood that within the scope of the appended claims, the invention may be practiced otherwise than using the example embodiments which have been specifically described. For that reason the following claims should be studied to determine the true scope and content of this invention.

What is claimed is:

1. A device for allowing current flowing in each branch of a multi-channel circuit to be evaluated, the device comprising:
secondary branches in parallel with each other and which each receive a resistive component of variable resistance that varies according to a common variation law;
a main branch with a resistive component of predetermined resistance, the main branch being connected in series with the secondary branches; and
a control unit that analyzes voltages measured across terminals of the resistive components of the main branch and the secondary branches and as a function of the predetermined resistance of the resistive component of the main branch and that deduces a value of current flowing through the resistive components of the main branch and the secondary branches.

2. The device as recited in claim 1, wherein the resistive component of the main branch is a shunt.

3. The device as recited in claim 1, wherein the resistive components of the secondary branches have a characteristic that varies as a function of temperature.

4. The device as recited in claim 1, wherein the resistive components of the secondary branches have a resistance that varies as a function of temperature.

5. The device as recited in claim 4, wherein the resistive components of the secondary branches are customized for each of the secondary branches as a function of nominal current that flows through the resistive components of the secondary branches, and all the resistive components of the secondary branches vary according to a common law as a function of temperature.

6. The device as recited in claim 1, wherein the control unit determines a global temperature of the device.

7. An architecture of a vehicle electrical system, the architecture comprising:
a device allowing current flowing in each branch of a multi-channel circuit to be evaluated, the device including:
secondary branches in parallel with each other and which each receive a resistive component of variable resistance that varies according to a common variation law;
a main branch with a resistive component of predetermined resistance, the main branch being connected in series with the secondary branches; and
a control unit that analyzes voltages measured across terminals of the resistive components of the main branch and the secondary branches and as a function of the predetermined resistance of the resistive component of the main branch and that deduces a value of current flowing through the resistive components of the main branch and the secondary branches.

8. The architecture as recited in claim 7, wherein at least one of the secondary branches is chosen from a group consisting of a power supply circuit of a power window motor, a power supply circuit of a rear-view mirror actuator motor, a power supply circuit of a lock actuating motor, a power supply circuit of a sun-roof actuating motor and a power supply circuit of a seat actuating motor.

9. A method for determining electrical current intensity in each branch of a device, the device including:
secondary branches in parallel with each other and which each receive a resistive component of variable resistance that varies according to a common variation law,
a main branch with a resistive component of predetermined resistance, the main branch being connected in series with the secondary branches, and
a control unit that analyzes voltages measured across terminals of the resistive components of the main branch and the secondary branches and as a function of the predetermined resistance of the resistive component of the main branch and that deduces a value of current flowing through the resistive components of the main branch and the secondary branches, the method comprising the steps of:
measuring the voltage across the terminals of the resistive components of the main branch and the secondary branches; and
determining an intensity of the current in the main branch and the secondary branches as a function of a characteristic of the resistive component of the main branch.

10. The method as recited in claim 9, further including the step of determining a temperature of the device.
